(19) United States
(12) Patent Application Publication
(10) Pub. No.: US 2010/0081274 A1
(43) Pub. Date: Apr. 1, 2010

(54) METHOD FOR FORMING RUTHENIUM METAL CAP LAYERS

(75) Inventors: Tadahiro Ishizaka, Watervliet, NY (US); Shigeru Mizuno, Delmar, NY (US); Frank M. Cerio, JR., Albany, NY (US)

Correspondence Address: Tokyo Electron U.S. Holdings, Inc., 4350 West Chandler Blvd., Suite 10/11, Chandler, AZ, 85226, US

(73) Assignee: Tokyo Electron Limited, Tokyo (JP)

(21) Appl. No.: 12/240,894

(22) Filed: Sep. 29, 2008

(51) Int. Cl. H01L 21/4763

(52) U.S. Cl. 438/653; 438/686; 257/E21.495

(57) ABSTRACT

A method is provided for integrating ruthenium (Ru) metal deposition into manufacturing of semiconductor devices to improve electromigration and stress migration in copper (Cu) metal. Embodiments of the invention include treating patterned substrates containing metal layers and low-k dielectric materials with NHₓ (x≦3) radicals and H radicals to improve selective formation of ruthenium (Ru) metal cap layers on the metal layers relative to the low-k dielectric materials.

### CROSS-REFERENCE TO RELATED APPLICATIONS

The present invention is related to U.S. patent application Ser. No. 12/018,074, entitled METHOD FOR INTEGRATING SELECTIVE LOW-TEMPERATURE RUTHENIUM DEPOSITION INTO COPPER METALLIZATION OF A SEMICONDUCTOR DEVICE. The present invention is related to U.S. patent application Ser. No. 11/853,393, entitled METHOD FOR INTEGRATING SELECTIVE RUTHENIUM DEPOSITION INTO MANUFACTURING OF A SEMICONDUCTOR DEVICE. The present invention is related to U.S. patent application Ser. No. 12/173,814, entitled METHOD FOR FORMING RUTHENIUM METAL CAP LAYERS. The entire contents of these applications are incorporated herein by reference.

### FIELD OF THE INVENTION

The present invention relates to semiconductor processing and semiconductor devices, and more particularly, to a method of selective deposition of ruthenium (Ru) metal films for manufacturing semiconductor devices.

### BACKGROUND OF THE INVENTION

An integrated circuit contains various semiconductor devices and a plurality of conducting metal paths that provide electrical power to the semiconductor devices and allow these semiconductor devices to share and exchange information. Within the integrated circuit, metal layers are stacked on top of one another using intermetal or interlayer dielectric layers that insulate the metal layers from each other. Normally, each metal layer must form an electrical contact to at least one additional metal layer. Such electrical contact is achieved by etching a hole (i.e., a via) in the interlayer dielectric that separates the metal layers, and filling the resulting via with a metal to create an interconnect. A “via” normally refers to any recessed feature such as a hole, line or other similar feature formed within a dielectric layer that, when filled with metal, provides an electrical connection through the dielectric layer to a conductive layer underlying the dielectric layer. Similarly, recessed features connecting two or more vias are normally referred to as trenches.

The use of copper (Cu) metal in multilayer metallization schemes for manufacturing integrated circuits has created several problems that require solutions. For example, high mobility of Cu atoms in dielectric materials and Si can result in migration of Cu atoms into those materials, thereby forming electrical defects that can destroy an integrated circuit. Therefore, Cu metal layers, Cu filled trenches, and Cu filled vias are normally encapsulated with a barrier layer to prevent Cu atoms from diffusing into the dielectric materials. Barrier layers are normally deposited on trench and via sidewalls and bottoms prior to Cu deposition, and may include materials that are preferably non-reactive and immiscible in Cu, provide good adhesion to the dielectrics materials and can offer low electrical resistivity.

The electrical current density in an integrated circuit's interconnects significantly increases for each successive technology node. Because electromigration (EM) and stress migration (SM) lifetimes are inversely proportional to current density, EM and SM have fast become critical challenges. EM lifetime in Cu dual damascene interconnect structures is strongly dependent on atomic Cu transport at the interfaces of bulk Cu metal and surrounding materials (e.g., capping layer) which is directly correlated to adhesion at these interfaces. New capping materials that provide better adhesion and better EM lifetime have been studied extensively. For example, a cobalt-tungsten-phosphorus (CoWP) layer has been selectively deposited on bulk Cu metal using an electroless plating technique. The interface of CoWP and bulk Cu metal has superior adhesion strength that yields longer EM lifetime. However, maintaining acceptable deposition selectivity on bulk Cu metal, especially for tight pitch Cu wiring, and maintaining good film uniformity, has affected acceptance of this complex process. Furthermore, wet process steps using acidic solution may be detrimental to the use of CoWP.

Therefore, new methods are required for depositing metal cap layers that provide good adhesion to Cu and improved EM and SM properties of bulk Cu metal. In particular, these methods should provide good selectivity for metal deposition on metal surfaces compared to dielectric surfaces.

### SUMMARY OF THE INVENTION

Embodiments of the invention provide a method for integrating Ru deposition into manufacturing of semiconductor devices to improve electromigration and stress migration in Cu metallization. Embodiments of the invention may be applied to treating a planarized substrate containing Cu paths and dielectric regions prior to selectively forming Ru cap layers on the Cu paths relative to on the dielectric regions. The treating can remove residues and copper oxide from the planarized substrate. In one example, the residues may include organic materials that are used in a chemical mechanical planarization (CMP) process.

According to one embodiment of the invention, the method includes providing a patterned substrate in a plasma processing chamber, where the patterned substrate contains a recessed feature formed in a low-k dielectric material and a first metallization layer at the bottom of the recessed feature. The method further includes treating the patterned substrate with NHₓ (x≦3) radicals and H radicals formed in the plasma processing chamber from a first process gas containing NH₃; forming a first ruthenium (Ru) metal cap layer on the first metallization layer; depositing a barrier layer in the recessed feature, including on the low-k dielectric material and on the first Ru metal cap layer; and filling the recessed feature with copper (Cu) metal.

According to another embodiment of the invention, the method further includes, following the filling, forming a substantially planar surface with Cu paths and low-k dielectric regions; treating the Cu paths and the low-k dielectric regions with NHₓ (x≦3) radicals and H radicals formed in the plasma processing chamber from a second process gas comprising NH₃; and forming a second Ru metal cap layer on the treated Cu paths.

According to yet another embodiment of the invention, the method includes providing a patterned substrate on a substrate holder in a plasma processing chamber, where the patterned substrate has a substantially planar surface with Cu paths and low-k dielectric regions; treating the Cu paths and the low-k dielectric regions with NHₓ (x≦3) radicals and H radicals formed in the plasma processing chamber; and forming a Ru metal cap layer on the treated Cu paths.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1A shows C/Si, N/Si, and O/Si ratios of a surface of a low-k material following processing using different treating conditions according to embodiments of the invention;

FIG. 1B shows selectivity of Ru metal deposition on treated low-k material relative to on Cu metal according to embodiments of the invention;

FIGS. 2A and 2B show schematic cross-sectional views of a SiCOH low-k material containing hydrophobic and hydrophilic surfaces;

FIGS. 3A-3E show schematic cross-sectional views of integration of Ru metal cap layers in a dual damascene interconnect structure according to embodiments of the invention;

FIG. 4 depicts a schematic view of a plasma processing system for treating substrates according to an embodiment of the invention;

FIG. 5 depicts a schematic view of a thermal chemical vapor deposition (TCVD) system for depositing a Ru metal film according to an embodiment of the invention; and

FIG. 6 depicts a schematic view of another TCVD system for depositing a Ru metal film according to another embodiment of the invention.

### DETAILED DESCRIPTION OF SEVERAL EMBODIMENTS

Embodiments of the invention provide a method for integrating Ru metal cap layers into Cu metallization of semiconductor devices to improve electromigration (EM) and stress migration (SM) in the devices. The method provides improved selectivity for Ru metal cap layer deposition on metal surfaces such as Cu paths relative to on dielectric surfaces between the Cu paths. The selective Ru metal deposition results in reduced amount of Ru metal impurities on the dielectric regions between the Cu paths and an improved margin for line-to-line breakdown and electrical leakage performance.

One skilled in the relevant art will recognize that the various embodiments may be practiced without one or more of the specific details, or with other replacement and/or additional methods, materials, or component. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Furthermore, it is understood that the various embodiments shown in the figures are illustrative representations and are not necessary drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention.

Integration of low-k SiCOH materials into semiconductor manufacturing presents several problems. For example, these materials are brittle (i.e., have low cohesive strength, low elongation to break, and low fracture toughness), liquid water and water vapor reduce the cohesive strength of the material even further, and when carbon (C) is bound as Si—CH₃ groups, low-k SiCOH materials readily react with resist strip plasmas and other integration processes, thereby damaging these materials. In order to improve selectivity of a Ru metal cap layer deposition on Cu paths relative to on dielectric regions, the current inventors have studied the effects of different surface treatments of substrates containing Cu metal and substrates containing a low-k dielectric material prior to Ru metal deposition. Low-k dielectric materials are dielectric materials that have a lower dielectric constant (k) than SiO₂ (k˜3.9).

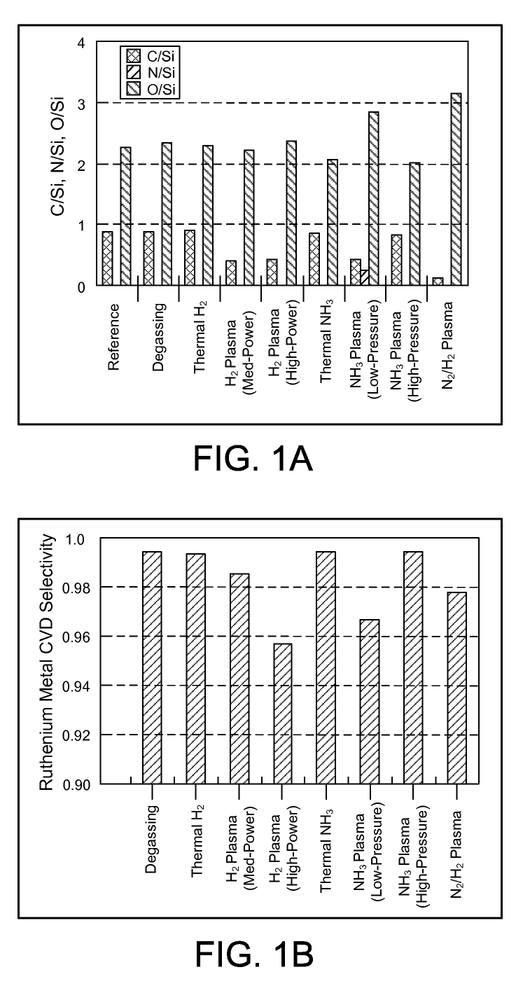

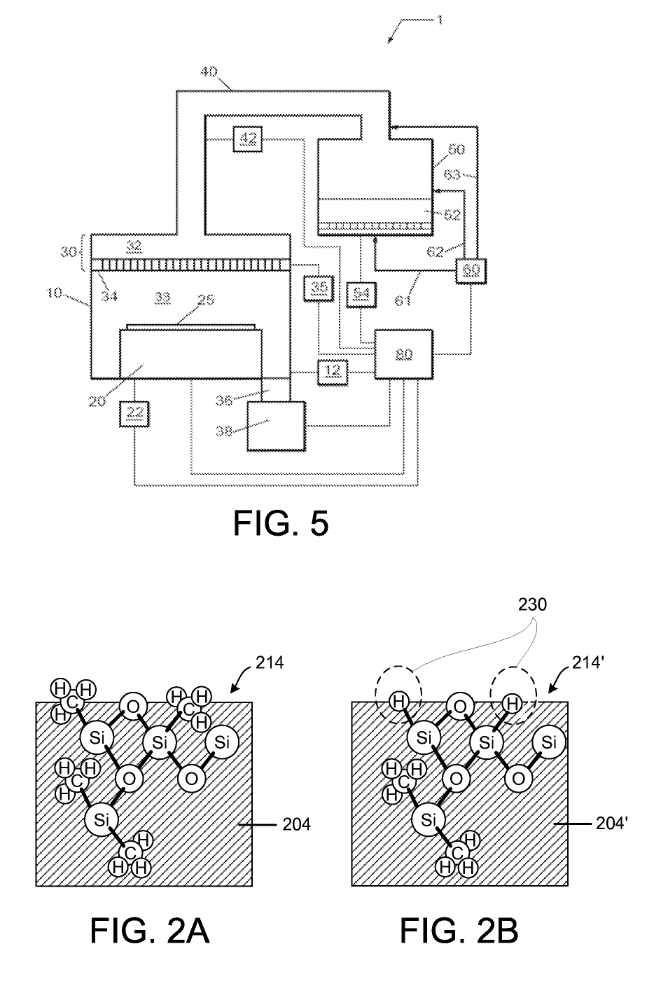

FIG. 1A shows carbon(C)/Si, nitrogen(N)/Si, and oxygen(O)/Si ratios from X-ray Photoelectron Spectroscopy (XPS) measurements of an as-received low-k material surface and of the low-k material surface following processing using different treating (processing) conditions. The low-k material studied was a BLACK DIAMOND® II (BDII) SiCOH material, commercially available from Applied Materials of Santa Clara, Calif. The BDII had a thickness of 150 nm deposited on 300 mm Si wafers. The Si wafers were introduced into a vacuum processing tool and, once in the vacuum processing tool, the Si wafers were initially degassed for 80 seconds at a substrate (wafer) temperature of 350° C. in an Argon (Ar) gas environment of 10 Torr. The degassing was performed to remove contaminants such as water and any other residual gas from surfaces of the SiCOH material.

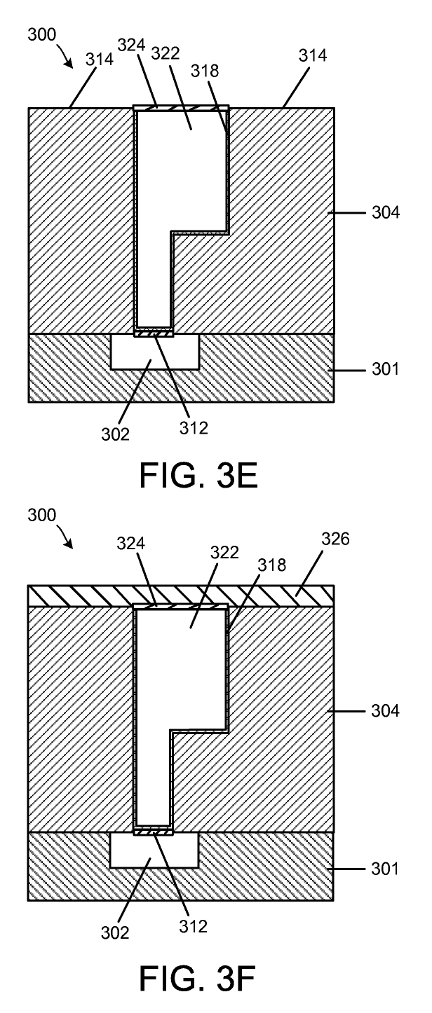

Following the degassing, some of the Si wafers were further processed using different treating conditions. Also referring to TABLE 1, the different treating conditions included 60 second process gas exposures at substrate temperature of 260° C. The treating conditions included treating condition #3) H₂ gas in a thermal (non-plasma) process at a gas pressure of 1.5 Torr; treating condition #4) H₂ gas that was plasma-excited using medium radio frequency (RF) power (700 W) and a gas pressure of 3 Torr; treating condition #5) H₂ gas that was plasma-excited using high RF power (1000 W) and a gas pressure of 3 Torr; treating condition #6) NH₃ gas in a thermal (non-plasma) process and a gas pressure of 1 Torr; treating condition #7) NH₃ gas that was plasma-excited using low RF power of 50 W and a gas pressure of 1 Torr; treating condition #8) NH₃ gas that was plasma-excited using low RF power of 50 W and a gas pressure of 3 Torr; and treating condition #9) N₂/H₂ gas mixture (500 sccm N₂+2000 sccm H₂) that was plasma-excited using low RF power of 50 W and a gas pressure of 1 Torr. The processing using treating conditions #3)-#6) was performed in a plasma processing chamber containing a slotted plane antenna (SPA). A plasma processing chamber containing a SPA is described in U.S. Pat. No. 5,024,716, entitled “Plasma processing apparatus for etching, ashing, and film-formation”; the contents of which is herein incorporated by reference in its entirety. The processing using treating conditions #7)-#9) were performed in plasma processing system schematically described in FIG. 4.

TABLE 1

| Treating | | Degas | | Treating Conditions | | | | |
|---|---|---|---|---|---|---|---|---|
| Condition | | T | t | | T | P | RF Power | t |
| No. | | (° C.) | (sec) | Gas | (° C.) | (Torr) | (W) | (sec) |
| 1 | Reference | — | — | — | — | — | — | — |
| 2 | Degas Only | 350 | 80 | — | — | — | — | — |
| 3 | Thermal H₂ | 350 | 80 | H₂ | 260 | 1.5 | — | 60 |
| 4 | H₂ Plasma, Med RF | 350 | 80 | H₂ | 260 | 3 | 700 | 60 |
| 5 | H₂ Plasma, High RF | 350 | 80 | H₂ | 260 | 3 | 1000 | 60 |
| 6 | Thermal NH₃ | 350 | 80 | NH₃ | 260 | 1 | — | 60 |
| 7 | NH₃ Plasma | 350 | 80 | NH₃ | 260 | 1 | 50 | 60 |
| 8 | NH₃ Plasma, High P | 350 | 80 | NH₃ | 260 | 3 | 50 | 60 |
| 9 | H₂/N₂ Plasma | 350 | 80 | N₂/H₂ | 260 | 1 | 50 | 60 |

Following the processing described in Table 1, the Si wafers were removed from the vacuum processing tool and the C/Si, N/Si, and O/Si ratios were measured in air by XPS. In TABLE 1 and FIG. 1A, the Reference sample refers to an as-received SiCOH material that was not degassed or further treated before XPS analysis. FIG. 1A shows that plasma processing using treating conditions #4), #5), #7), and #9) resulted in low C/Si ratios and high O/Si ratios relative to treating condition #1) SiCOH Reference (no treating), treating condition #2) Degas only, non-plasma processing using treating conditions #3) and #6), and processing using treating condition #8) using NH₃ gas that was plasma-excited at high gas pressure to form NHₓ (x≦3) radicals and H radicals.

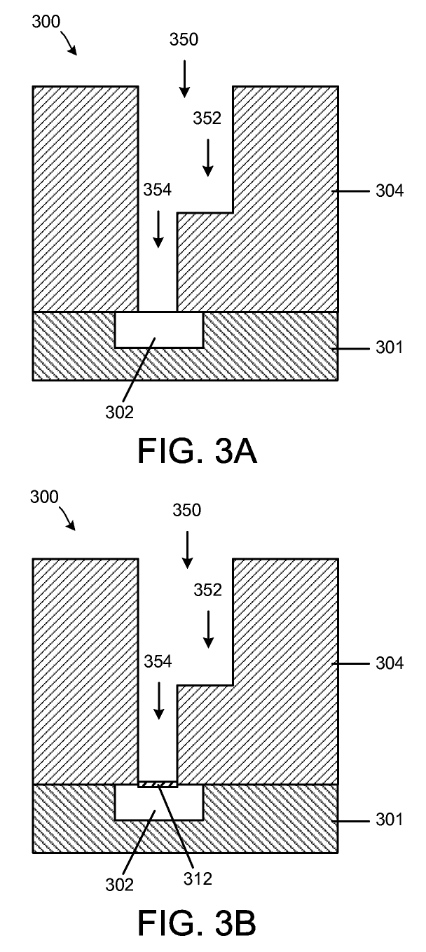

FIGS. 2A and 2B show schematic cross-sectional views of a SiCOH low-k material containing hydrophobic and hydrophilic surfaces, respectively. FIG. 2A schematically shows a SiCOH low-k material 204 containing a hydrophobic surface 214. The surface 214 contains few or no metal precursor adsorption sites and thus an exposure of the surface 214 to a metal precursor results in a long incubation time and delayed metal deposition on the hydrophobic surface 214.

FIG. 2B schematically shows a SiCOH low-k material 204′ containing a hydrophilic surface 214′. The hydrophilic surface 214′ contains a plurality of metal precursor adsorption sites 230 that are formed by removal of CHₓ groups from the surface 214 in FIG. 2A. The presence of the adsorptions sites 230 is thought to significantly reduce the incubation time for metal deposition compared to the hydrophobic surface 214 in FIG. 2A. Referring back to FIG. 1A, it is believed that the low C/Si ratios observed for plasma processing using treating conditions #4), #5), #7), and #9) are due to CHₓ removal from the hydrophobic surface 214 by the plasma processing, thereby forming the hydrophilic surface 214′. However, the present inventors have discovered that a plasma processing using treating condition #8) does not significantly change the C/Si ratio. This result is thought to be due to exposure of the SiCOH low-k material to NHₓ (x≦3) radicals and H radicals in the plasma using treating condition #8), compared to exposure of the SiCOH low-k material to H ions and NHₓ (x<3) ions in the plasma processing using treating conditions #4), #5), #7), and #9). According to embodiments of the invention, hydrophobic surface 214 is preferred for Ru metal cap layer deposition since it enables and enhances selective Ru metal cap layer deposition on Cu metal and other metals that have a short incubation time for Ru metal deposition.

FIG. 1B shows selectivity of Ru metal deposition on treated low-k materials relative to on Cu metal according to embodiments of the invention. The different treating conditions were described above in reference to FIG. 1A. Following each treating process, Ru metal films were deposited in-situ without exposing the treated low-k material to air. For comparison, Ru metal films were also deposited on Cu metal films formed on 300 mm Si wafers by ionized physical vapor deposition (IPVD). All the Ru metal films were deposited in a thermal CVD process (non-plasma) using a process gas containing Ru₃(CO)₁₂ precursor vapor and CO carrier gas. The Si wafers were exposed to the process gas for 60 seconds at a substrate temperature of 190° C. to form a Ru metal film with a thickness of 4-5 nm on the Cu metal films but only trace amounts of Ru metal on the low-k material surfaces. The Ru metal film thickness on the Cu metal films is comparable to a thickness that may used in Ru metal cap layers on Cu paths and metallization layers in semiconductor devices.

In FIG. 1B, Ru metal CVD selectivity (SRU) was calculated according to equation (1):

S_{Ru}=(Ru_{Cu}−Ru_{low-k})/Ru_{Cu} (1)

where Ru_{Cu} refers to the amount of Ru metal deposited on the Cu metal films and Ru_{low-k} refers to the amount of Ru metal deposited on the low-k materials. According to equation (1), a selectivity of 1 refers to ideal selective Ru metal deposition on the Cu metal film relative to on the low-k material and a selectivity of 0 refers to non-selective deposition of Ru metal on the Cu metal and on the low-k material. Ru_{Cu} and Ru_{low-k} were measured ex-situ by X-ray fluorescence (XRF) spectroscopy. Examples of Ru metal deposition processes using Ru₃(CO)₁₂ and CO carrier gas are described in U.S. Pat. No. 7,270,848 and U.S. patent application Ser. Nos. 11/853,393 (Docket No. TTCA-227) and 12/018,074 (Docket No. TTCA-256). The entire contents of these applications are incorporated herein by reference.

Referring also to Table 1, FIG. 1B shows that Ru metal deposition selectivity was highest for the low-k material that was only degassed, the low-k material that was thermally processed (non-plasma) in H₂ gas, or plasma processed in NH₃ gas at high gas pressure. In comparison, Ru metal deposition selectivity was significantly reduced for the low-k material that was plasma processed using treating conditions #4), #5), #7), and #9).

In summary, the experimental results shown in FIGS. 1A and 1B show that high C/Si ratios may be correlated with high Ru metal deposition selectivity. Although low-k material that was only degassed showed good Ru metal deposition selectivity, degassing alone is not efficient for removing oxidized Cu formed on Cu paths. However, according to embodiments of the invention, processing (treating) the patterned substrate with NHₓ (x≦3) radicals and H radicals at high gas pressure removes oxidized Cu from the Cu paths and provides excellent Ru metal deposition selectivity on the Cu paths.

Embodiments of the invention provide a method for highly selective deposition of Ru metal films on treated metal surfaces (e.g., Cu metal) on patterned substrates containing low-k materials. The patterned substrates can contain high-aspect-ratio recessed features in a low-k dielectric material that are at least substantially filled with Cu metal, thus forming Cu paths in the recessed features. According to one embodiment of the invention, a recessed feature can include a dual damascene interconnect structure containing a trench and a via formed in the patterned substrate. The via can have an aspect ratio (depth/width) greater than or equal to about 2:1, for example 3:1, 4:1, 5:1, 6:1, 12:1, 15:1, or higher. The via can have widths of about 200 nm or less, for example 150 nm, 100 nm, 65 nm, 45 nm, 32 nm, 20 nm, or lower. However, embodiments of the invention are not limited to these aspect ratios or via widths, as other aspect ratios or via widths may be utilized.

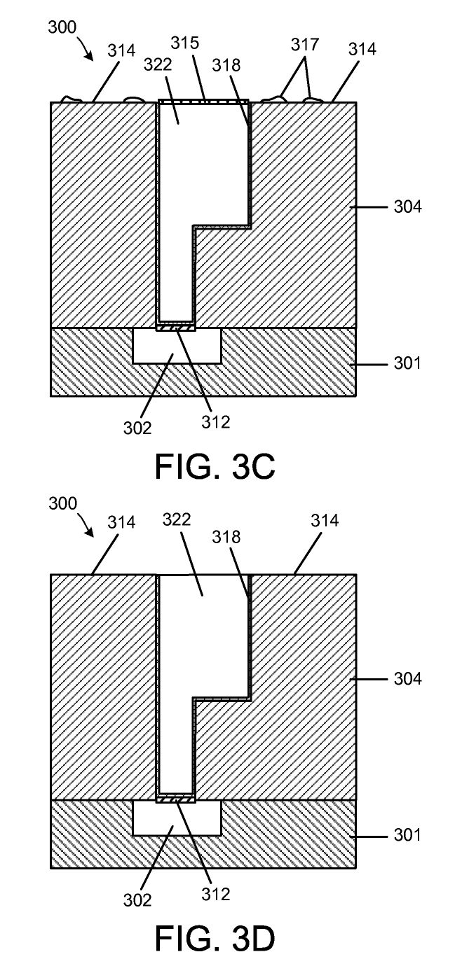

FIGS. 3A-3E show schematic cross-sectional views of integration of Ru metal films in a dual damascene interconnect structure according to embodiments of the invention. FIG. 3A shows a schematic cross-sectional view of a patterned substrate containing dual damascene interconnect structure 300 according to an embodiment of the invention. The dual damascene interconnect structure 300 can be formed using standard lithography and etching methods known to those skilled in the art. It will be understood that embodiments of the invention may also be applied to simpler or more complicated dual damascene interconnect structures and other types of recessed features formed in low-k materials.

In FIG. 3A, the dual damascene interconnect structure 300 comprises a recessed feature 350 containing a trench 352 and a via 354 etched in a dielectric layer 304. Furthermore, the dual damascene interconnect structure 300 contains a metallization layer 302 (e.g., Cu metal or tungsten (W) metal) at the bottom of the via 354. The dielectric layer 304 can, for example, contain a low-k dielectric material such as fluorinated silicon glass (FSG), carbon doped oxide, a polymer, a SiCOH-containing low-k material, a non-porous low-k material, a porous low-k material, a CVD low-k material, a spin-on dielectric (SOD) low-k material, or any other suitable dielectric material. In addition to BD II, other carbon-containing materials are commercially available, including Silk® and Cyclotene® (benzocyclobutene) available from Dow Chemical. Although not shown, the interconnect structure 300 may contain additional layers, for example a trench etch stop layer, a via etch stop layer between dielectric layers 301 and 304, and a barrier layer separating the metallization layer 302 from the dielectric layer 301.

According to one embodiment of the invention, the patterned substrate depicted in FIG. 3A is treated with NHₓ (x≦3) radicals and H radicals formed in a plasma processing chamber from a process gas comprising NH₃. The treating can include heating the patterned substrate to a substrate temperature below 500° C., for example between 150° C. and 400° C., and may further include a noble gas such as argon (Ar). In one example, pure NH₃ may be used. In one example, a 10:1 NH₃/Ar mixture may be used. In one example, a gas pressure of the process gas in the plasma processing chamber is greater than 1 Torr, for example 2 Torr, 3 Torr, or greater than 3 Torr. In one example, a plasma is generated in the plasma processing chamber by applying RF power of less than 100 W to a substrate holder configured to support the substrate (wafer). The RF power can, for example, include 90, 80, 70, 60, 50, or even less than 50 Watts (W). According to embodiments of the invention, during the treating, plasma conditions are selected such that exposure of the substrate to ions formed in the plasma is suppressed. This may be achieved using low plasma power and high gas pressure of the process gas that exposes the substrate to NHₓ (x≦3) radicals and H radicals to but suppresses exposure of the substrate to ions formed in the plasma.

Following the treating, a first Ru metal cap layer 312 may be formed on the metallization layer 302 as shown in FIG. 3B. According to one embodiment of the invention, the first Ru metal cap layer 312 may be selectively deposited on the metallization layer 302. The first Ru metal cap layer 312 can, for example, be deposited while heating the patterned substrate to a substrate temperature between 100° C. and 300° C. The first Ru metal cap layer 312 can be deposited in a TCVD process using a process gas containing Ru₃(CO)₁₂ precursor vapor and a CO gas. In one example, an average thickness of the first Ru metal cap layer 312 can be between 2 angstrom (angstrom=10⁻¹⁰ m) and 100 angstrom, for example about 2, 5, 10, 15, 20, 30, 40, 50, 60, 70, 80, 90, or 100 angstrom. However, embodiments of the invention are not limited to those thicknesses and thicker first Ru metal cap layer 312 may be formed and utilized. According to one embodiment, a surface coverage of the first Ru metal cap layer 312 on the metallization layer 302 may be incomplete with gaps that expose the metallization layer 302. According to one embodiment, the treating and the deposition of the first Ru metal film may be performed in the same process chamber. Alternately, the treating and the Ru metal film deposition may be performed in different process chambers.

According to other embodiments of the invention, the first Ru metal cap layer 312 may be omitted from the dual damascene interconnect structure 300 depicted in FIG. 3B.

FIG. 3C schematically shows a barrier layer 318 is formed in the recessed feature 350 and a planarized Cu path 322 formed on the barrier layer 318 in the recessed feature 350. The planarized Cu path 322 can be formed by filling the recessed feature 350 with bulk Cu metal and removing excess Cu metal using a planarizing process, for example a chemical mechanical polishing (CMP) process. The planarization process further removes the barrier layer 318 from the low-k dielectric regions 314 as schematically shown in FIG. 3C. Bulk Cu metal deposition processes are well known to one of ordinary skill in the art of circuit fabrication and can, for example, include an electrochemical plating process or an electroless plating process. Furthermore, CMP processes are well known to one of ordinary skill in the art. Although only a single Cu path 322 is depicted in FIG. 3C, those skilled in the art will readily recognize that semiconductor devices contain a plurality of Cu paths 322.

The barrier layer 318 can, for example, contain a tantalum(Ta)-containing material (e.g., Ta, TaC, TaN, or TaCN, or a combination thereof), a titanium(Ti)-containing material (e.g., Ti, TiN, or a combination thereof), or a tungsten(W)-containing material (e.g., W, WN, or a combination thereof). In one example, the barrier layer 318 may contain TaCN deposited in a plasma enhanced atomic layer deposition (PEALD) system using alternating exposures of tertiary amyl imido-tris-dimethylamido tantalum (Ta(NC(CH₃)₂C₂H₅)(N(CH₃)₂)₃) and H₂. In another example, the barrier layer 318 may contain a Ru metal layer formed on a Ta-containing layer or on a Ti-containing layer, e.g., Ru/TaN, Ru/TaCN, Ru/TiN, or Ru/TiCN. In yet another example, the barrier layer 318 may contain a mixture of Ru and a Ta-containing material or a mixture of Ru and a Ti-containing material, e.g., RuTaN, RuTaCN, RuTiN, or RuTiCN.

Still referring to FIG. 3C, the low-k dielectric regions 314 contain residues 317 and a copper oxide layer 315 formed on the Cu path 322. The residues 317 and the copper oxide layer 315 may be formed by a CMP process. The residues 317 may include benzotriazine (BTA) that is a chemical agent commonly used in a CMP process. According to another embodiment, the residues 317, the copper oxide layer 315, or both the residues 317 and the copper oxide layer 315 may be absent from the structure in FIG. 3C.

According to one embodiment of the invention, following formation of the dual damascene interconnect structure 300 in FIG. 3C, the planarized bulk Cu path 322 and the low-k dielectric regions 314 are treated with NHₓ (x≦3) radicals and H radicals generated in a plasma from a process gas containing NH₃. The resulting structure is shown in FIG. 3D. The treating can include heating the patterned substrate to a substrate temperature below 500° C., for example between 150° C. and 400° C., and may further include a noble gas such as argon (Ar). In one example, pure NH₃ may be used. In one example, a 10:1 NH₃/Ar mixture may be used. In one example, a gas pressure of the process gas in the plasma processing chamber is greater than 1 Torr, for example 2 Torr, 3 Torr, or greater than 3 Torr. In another example, a plasma is generated in the plasma processing chamber by applying RF power of less than 100 W to a substrate holder configured to support the substrate (wafer). According to embodiments of the invention, during the treating, plasma conditions are selected such that exposure of the substrate to ions formed in the plasma is suppressed. This is achieved using low plasma power and high gas pressure of the process gas that exposes the substrate to NHₓ (x≦3) radicals and H radicals to but suppresses exposure of the substrate to ions formed in the plasma.

Following the treating, a second Ru metal cap layer 324 is selectively deposited on the treated planarized Cu path 322, as shown in FIG. 3E. The second Ru metal cap layer 324 can, for example, be deposited while heating the patterned substrate to a substrate temperature between 100° C. and 300° C. The second Ru metal cap layer 324 can be deposited in a TCVD process using a process gas containing Ru₃(CO)₁₂ precursor vapor and a CO gas. In one example, an average thickness of the second Ru metal cap layer 324 can be between 2 angstrom (angstrom=10 μm) and 100 angstrom, for example about 2, 5, 10, 15, 20, 30, 40, 50, 60, 70, 80, 90, or 100 angstrom. However, embodiments of the invention are not limited to those thicknesses and thicker second Ru metal cap layer 324 may be formed and utilized.

According to one embodiment, a surface coverage of the second Ru metal cap layer 324 on the Cu path 322 may be incomplete with gaps that expose the planarized Cu path 322. According to one embodiment, the treating and the Ru metal film deposition may be performed in the same process chamber. Alternately, the treating and the Ru metal film deposition may be performed in different process chambers.

Following selective deposition of the second Ru metal cap layer 324 on the Cu path 322, the partially manufactured semiconductor device depicted in FIG. 3E is further processed. FIG. 3F shows a conformal cap layer 326 deposited on the second Ru metal cap layer 324 and on the low-k dielectric regions 314. The cap layer 326 can, for example, contain silicon nitride or silicon carbon nitride. According to one embodiment of the invention, prior to depositing the cap layer 326, the second Ru metal cap layer 324 and the low-k dielectric regions 314 may be treated in a plasma process or in a non-plasma process while heating the patterned substrate to a substrate temperature between 150° C. and 400° C. in the presence of H₂, N₂, or NH₃, or a combination thereof. In one example, the second Ru metal cap layer 324 and the low-k dielectric regions 314 may be treated with NHₓ (x≦3) radicals and H radicals as described above.

FIG. 4 depicts a schematic view of a plasma processing system for treating substrates according to an embodiment of the invention. The plasma processing system 400 comprises a process chamber 410 having a substrate holder 420 configured to support a substrate 425. The process chamber 410 further comprises an upper assembly 430 coupled to process gas supply system 440 and a purge gas supply system 442. Additionally, the plasma processing system 400 includes a substrate temperature control system 460 coupled to substrate holder 420 and configured to elevate and control the temperature of substrate 425.

Still referring to FIG. 4, the plasma processing system 400 may be configured to process 200 mm substrates, 300 mm substrates, or larger-sized substrates. In fact, it is contemplated that the deposition system may be configured to process substrates, wafers, or LCDs regardless of their size, as would be appreciated by those skilled in the art. Therefore, while aspects of the invention will be described in connection with the processing of a semiconductor substrate, the invention is not limited solely thereto.

The process gas supply system 440 is configured for introducing a process gas to the process chamber 410. According to embodiments of the invention, the process gas can contain NH₃, or NH₃ and an inert gas. Additionally, the purge gas supply system 442 can be configured to introduce a purge gas to process chamber 410.

Referring still to FIG. 4, the plasma processing system 400 includes a plasma generation system 451 configured to generate a plasma during at least a portion of the introduction of the process gas to process chamber 410. The plasma generation system 451 can include first power source 450 coupled to the process chamber 410, and configured to couple power to the process chamber 410. The first power source 450 may be a variable power source and may include a radio frequency (RF) generator and an impedance match network, and may further include an electrode through which RF power is coupled to the plasma in process chamber 410. The electrode can be formed in the upper assembly 430, and it can be configured to oppose the substrate holder 420. The impedance match network can be configured to optimize the transfer of RF power from the RF generator to the plasma by matching the output impedance of the match network with the input impedance of the process chamber, including the electrode, and plasma. For instance, the impedance match network serves to improve the transfer of RF power to plasma in process chamber 410 by reducing the reflected power. Match network topologies (e.g. L-type, π-type, T-type, etc.) and automatic control methods are well known to those skilled in the art.

Alternatively, the first power source 450 may include a RF generator and an impedance match network, and may further include an antenna, such as an inductive coil, through which RF power is coupled to plasma in process chamber 410. The antenna can, for example, include a helical or solenoidal coil, such as in an inductively coupled plasma source or helicon source, or it can, for example, include a flat coil as in a transformer coupled plasma source.

Alternatively, the first power source 450 may include a microwave frequency generator, and may further include a microwave antenna and microwave window through which microwave power is coupled to plasma in process chamber 410. The coupling of microwave power can be accomplished using electron cyclotron resonance (ECR) technology, or it may be employed using surface wave plasma technology, such as a slotted plane antenna (SPA), as described in U.S. Pat. No. 5,024,716, entitled “Plasma processing apparatus for etching, ashing, and film-formation”; the contents of which are herein incorporated by reference in its entirety.

According to one embodiment of the invention, the plasma processing system 400 includes a substrate bias generation system 453 configured to generate or assist in generating a plasma 446 through biasing of substrate holder 420 during at least a portion of the introduction of the process gas to process chamber 410. The substrate bias generation system 453 can include a substrate power source 452 coupled to the process chamber 410, and configured to couple power to substrate 425. The substrate power source 452 may include a RF generator and an impedance match network, and may further include an electrode through which RF power is coupled to substrate 425. The electrode can be formed in substrate holder 420. For instance, substrate holder 420 can be electrically biased at a RF voltage via the transmission of RF power from a RF generator (not shown) through an impedance match network (not shown) to substrate holder 420. A typical frequency for the RF bias can range from about 0.1 MHz to about 100 MHz, and can be 13.56 MHz. RF bias systems for plasma processing are well known to those skilled in the art. Alternatively, RF power is applied to the substrate holder electrode at multiple frequencies.

Although the plasma generation system 451 and the substrate bias generation system 453 are illustrated in FIG. 4 as separate entities, they may indeed comprise one or more power sources coupled to substrate holder 420.

Still referring to FIG. 4, the plasma processing system 400 includes substrate temperature control system 460 coupled to the substrate holder 420 and configured to elevate and control the temperature of substrate 425. Substrate temperature control system 460 comprises temperature control elements, such as a cooling system including a re-circulating coolant flow that receives heat from substrate holder 420 and transfers heat to a heat exchanger system (not shown), or when heating, transfers heat from the heat exchanger system. Additionally, the temperature control elements can include heating/cooling elements, such as resistive heating elements, or thermoelectric heaters/coolers, which can be included in the substrate holder 420, as well as the chamber wall of the process chamber 410 and any other component within the plasma processing system 400.

In order to improve the thermal transfer between substrate 425 and substrate holder 420, substrate holder 420 can include a mechanical clamping system, or an electrical clamping system, such as an electrostatic clamping system, to affix substrate 425 to an upper surface of substrate holder 420. Furthermore, substrate holder 420 can further include a substrate backside gas delivery system configured to introduce gas to the back-side of substrate 425 in order to improve the gas-gap thermal conductance between substrate 425 and substrate holder 420. Such a system can be utilized when temperature control of the substrate is required at elevated or reduced temperatures. For example, the substrate backside gas system can comprise a two-zone gas distribution system, wherein the helium gas gap pressure can be independently varied between the center and the edge of substrate 425.

Furthermore, the process chamber 410 is further coupled to a pressure control system 432, including a vacuum pumping system 434 and a valve 436, through a duct 438, wherein the pressure control system 432 is configured to controllably evacuate the process chamber 410 to a pressure suitable for treating substrate 425. The vacuum pumping system 434 can include a turbo-molecular vacuum pump (TMP) or a cryogenic pump capable of a pumping speed up to about 5000 liters per second (and greater) and valve 436 can include a gate valve for throttling the chamber pressure. Moreover, a device for monitoring chamber pressure (not shown) can be coupled to the process chamber 410. The pressure measuring device can be, for example, a an absolute capacitance manometer

Still referring to FIG. 4, controller 470 can comprise a microprocessor, memory, and a digital I/O port capable of generating control voltages sufficient to communicate and activate inputs to plasma processing system 400 as well as monitor outputs from plasma processing system 400. Moreover, the controller 470 may be coupled to and may exchange information with the process chamber 410, substrate holder 420, upper assembly 430, process gas supply system 440, purge gas supply system 442, first power source 450, substrate power source 452, substrate temperature control system 460, and pressure control system 432. For example, a program stored in the memory may be utilized to activate the inputs to the aforementioned components of the plasma processing system according to a process recipe in order to perform treating process.

However, the controller 470 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 470 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the controller 470, for driving a device or devices for implementing the invention, and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 470 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to processor of controller for execution. For example, the instructions may initially be carried on a magnetic disk of a remote computer. The remote computer can load the instructions for implementing all or a portion of the present invention remotely into a dynamic memory and send the instructions over a network to the controller 470.

The controller 470 may be locally located relative to the plasma processing system 400, or it may be remotely located relative to the plasma processing system 400. For example, the controller 470 may exchange data with the plasma processing system 400 using at least one of a direct connection, an intranet, the Internet and a wireless connection. The controller 470 may be coupled to an intranet at, for example, a customer site (i.e., a device maker, etc.), or it may be coupled to an intranet at, for example, a vendor site (i.e., an equipment manufacturer). Additionally, for example, the controller 470 may be coupled to the Internet. Furthermore, another computer (i.e., controller, server, etc.) may access, for example, the controller 470 to exchange data via at least one of a direct connection, an intranet, and the Internet. As also would be appreciated by those skilled in the art, the controller 470 may exchange data with the plasma processing system 400 via a wireless connection.

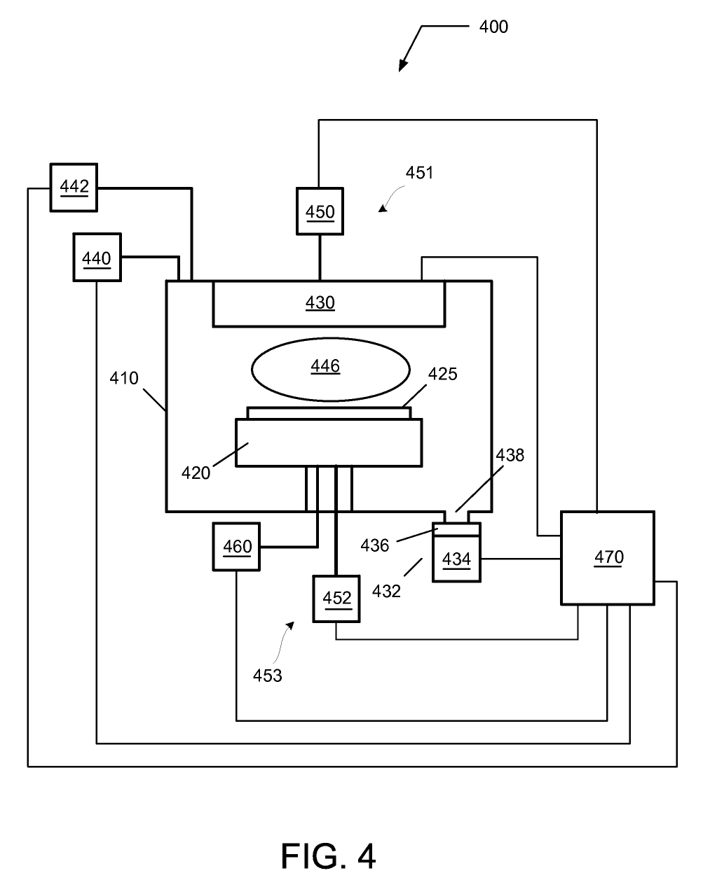

FIG. 5 depicts a schematic view of a thermal chemical vapor deposition (TCVD) system 1 for depositing a Ru metal film from a Ru₃(CO)₁₂ precursor vapor and a CO gas according to an embodiment of the invention. The deposition system 1 includes a process chamber 10 having a substrate holder 20 configured to support a patterned substrate 25 upon which the Ru metal film is formed. The process chamber 10 is coupled to a metal precursor vaporization system 50 via a vapor precursor delivery system 40.

The process chamber 10 is further coupled to a vacuum pumping system 38 through a duct 36, wherein the vacuum pumping system 38 is configured to evacuate the process chamber 10, vapor precursor delivery system 40, and metal precursor vaporization system 50 to a pressure suitable for forming the Ru metal film on the patterned substrate 25, and suitable for vaporization of the Ru₃(CO)₁₂ precursor 52 in the metal precursor vaporization system 50.

Still referring to FIG. 5, the metal precursor vaporization system 50 is configured to store a Ru₃(CO)₁₂ precursor 52, to heat the Ru₃(CO)₁₂ precursor 52 to a temperature sufficient for vaporizing the Ru₃(CO)₁₂ precursor 52, and to introduce Ru₃(CO)₁₂ precursor vapor to the vapor precursor delivery system 40. The Ru₃(CO)₁₂ precursor 52 is a solid under the selected heating conditions in the metal precursor vaporization system 50. In order to achieve the desired temperature for subliming the solid Ru₃(CO)₁₂ precursor 52, the metal precursor vaporization system 50 is coupled to a vaporization temperature control system 54 configured to control the vaporization temperature.

For instance, the temperature of the Ru₃(CO)₁₂ precursor 52 may be elevated to between approximately 40° C. to approximately 150° C. Alternately, the vaporization temperature can be maintained at approximately 60° C. to approximately 90° C. As the Ru₃(CO)₁₂ precursor 52 is heated to cause sublimation, a CO-containing gas is passed over or through the Ru₃(CO)₁₂ precursor 52 to capture the Ru₃(CO)₁₂ precursor vapor as it is being formed. The CO-containing gas contains CO and optionally an inert carrier gas, such as N₂, or a noble gas (i.e., He, Ne, Ar, Kr, or Xe), or a combination thereof. Vaporizing the Ru₃(CO)₁₂ precursor in the presence of CO gas can reduce problems that limit the delivery of the Ru₃(CO)₁₂ precursor vapor to the patterned substrate. It has been shown that addition of the CO gas to the Ru₃(CO)₁₂ precursor vapor as it is being formed allows for increasing the vaporization temperature. The elevated temperature increases the vapor pressure of the Ru₃(CO)₁₂ precursor, resulting in increased delivery of the Ru₃(CO)₁₂ precursor to the process chamber and, hence, increased deposition rate of a Ru metal film on the patterned substrate 25. The use of a CO gas to reduce premature decomposition of the Ru₃(CO)₁₂ precursor in the vapor precursor delivery system 40 prior to delivery of the Ru₃(CO)₁₂ precursor to the process chamber 10 has been shown to facilitate efficient transfer of Ru₃(CO)₁₂ precursor vapor to a process chamber to deposit Ru metal film has been described in U.S. Pat. No. 7,270,848, the entire contents of which is incorporated herein by reference.

In one example, the metal precursor vaporization system 50 may be a multi-tray vaporization system configured for efficient evaporation and transport of the Ru₃(CO)₁₂ vapor. An exemplary multi-tray vaporization system is described in U.S. patent application Ser. No. 10/998,420, titled “Multi-Tray Film Precursor Evaporation System and Thin Film Deposition System Incorporating Same”, filed on Nov. 29, 2004.

For example, a gas supply system 60 is coupled to the metal precursor vaporization system 50, and the gas supply system 60 is configured to, for instance, supply CO, a carrier gas, or a mixture thereof, beneath the Ru₃(CO)₁₂ precursor 52 via feed line 61, or over the Ru₃(CO)₁₂ precursor 52 via feed line 62. In addition, the gas supply system 60 is coupled to the vapor precursor delivery system 40 downstream from the metal precursor vaporization system 50 to supply the gas to the vapor of the Ru₃(CO)₁₂ precursor 52 via feed line 63 as or after it enters the vapor precursor delivery system 40. Furthermore, the feed line 63 may be utilized to pre-treat the patterned substrate 25 with a pre-treatment gas containing CO gas to saturate the exposed surfaces of the patterned substrate 25 with adsorbed CO prior to exposing the patterned substrate 25 to Ru₃(CO)₁₂ precursor vapor and CO gas.

Although not shown, the gas supply system 60 can comprise a carrier gas source, a CO gas source, one or more control valves, one or more filters, and a mass flow controller. For instance, the flow rate of the CO-containing gas can be between about 0.1 standard cubic centimeters per minute (sccm) and about 1000 sccm. Alternately, the flow rate of the CO-containing gas can be between about 10 sccm and about 500 sccm. Still alternately, the flow rate of the CO-containing gas can be between about 50 sccm and about 200 sccm. According to embodiments of the invention, the flow rate of the CO-containing gas can range from approximately 0.1 sccm to approximately 1000 sccm. Alternately, the flow rate of the CO-containing gas can be between about 1 sccm and about 500 sccm.

Downstream from the metal precursor vaporization system 50, the process gas containing the Ru₃(CO)₁₂ precursor vapor and CO gas flows through the vapor precursor delivery system 40 until the process gas enters the process chamber 10 via a vapor distribution system 30 coupled thereto. The vapor precursor delivery system 40 can be coupled to a vapor line temperature control system 42 in order to control the vapor line temperature and prevent decomposition of the Ru₃(CO)₁₂ precursor vapor as well as condensation of the Ru₃(CO)₁₂ precursor vapor. The vapor precursor delivery system 40 can, for example, be maintained at a temperature between 50° C. and 100° C.

Still referring to FIG. 5, the vapor distribution system 30, which forms part of and is coupled to the process chamber 10, comprises a vapor distribution plenum 32 within which the vapor disperses prior to passing through a vapor distribution plate 34 and entering a processing zone 33 above the patterned substrate 25. In addition, the vapor distribution plate 34 can be coupled to a distribution plate temperature control system 35 configured to control the temperature of the vapor distribution plate 34.

Once the process gas containing the Ru₃(CO)₁₂ precursor vapor and CO gas enters the processing zone 33 of process chamber 10, the Ru₃(CO)₁₂ precursor vapor thermally decomposes upon adsorption at the substrate surface due to the elevated temperature of the patterned substrate 25, and a Ru metal film is formed on the patterned substrate 25. The substrate holder 20 is configured to elevate the temperature of the patterned substrate 25 by virtue of the substrate holder 20 being coupled to a substrate temperature control system 22. For example, the substrate temperature control system 22 can be configured to elevate the temperature of the patterned substrate 25 up to approximately 500° C. Additionally, the process chamber 10 can be coupled to a chamber temperature control system 12 configured to control the temperature of the chamber walls.

Still referring to FIG. 5, the deposition system 1 can further include a control system 80 configured to operate and control the operation of the deposition system 1. The control system 80 is coupled to the process chamber 10, the substrate holder 20, the substrate temperature control system 22, the chamber temperature control system 12, the vapor distribution system 30, the vapor precursor delivery system 40, the metal precursor vaporization system 50, and the gas supply system 60.

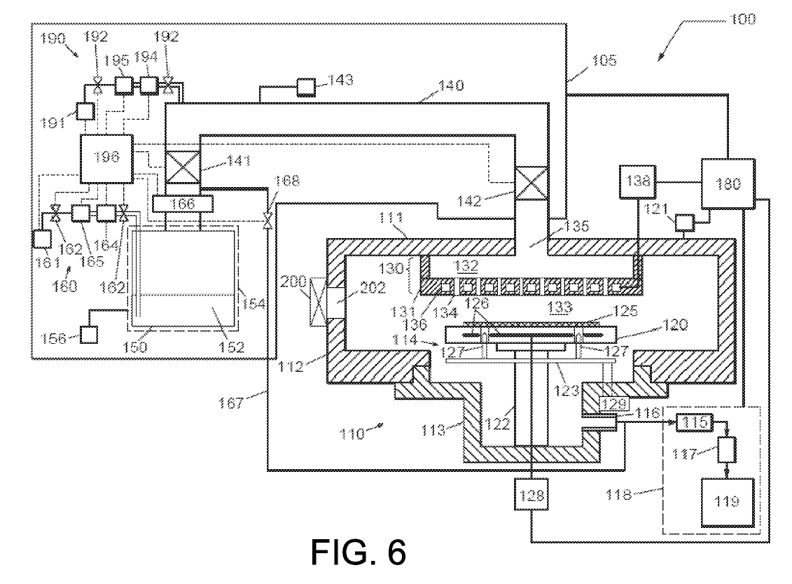

FIG. 6 depicts a schematic view of another TCVD system for depositing a Ru metal film from a Ru₃(CO)₁₂ precursor vapor and a CO gas according to an embodiment of the invention. The deposition system 100 comprises a process chamber 110 having a substrate holder 120 configured to support a patterned substrate 125 upon which the Ru metal film is formed. The process chamber 110 is coupled to a precursor delivery system 105 having metal precursor vaporization system 150 configured to store and vaporize a Ru₃(CO)₁₂ precursor 152, and a vapor precursor delivery system 140 configured to transport the vapor of the Ru₃(CO)₁₂ precursor 152 to the process chamber 110.

The process chamber 110 comprises an upper chamber section 111, a lower chamber section 112, and an exhaust chamber 113. An opening 114 is formed within lower chamber section 112, where lower chamber section 112 couples with exhaust chamber 113.

Still referring to FIG. 6, substrate holder 120 provides a horizontal surface to support a patterned substrate (or wafer) 125, which is to be processed. The substrate holder 120 can be supported by a cylindrical support member 122, which extends upward from the lower portion of exhaust chamber 113. Furthermore, the substrate holder 120 comprises a heater 126 coupled to substrate holder temperature control system 128. The heater 126 can, for example, include one or more resistive heating elements. Alternately, the heater 126 can, for example, include a radiant heating system, such as a tungsten-halogen lamp. The substrate holder temperature control system 128 can include a power source for providing power to the one or more heating elements, one or more temperature sensors for measuring the substrate temperature or the substrate holder temperature, or both, and a controller configured to perform at least one of monitoring, adjusting, or controlling the temperature of the patterned substrate 125 or substrate holder 120.

During processing, the heated patterned substrate 125 can thermally decompose the Ru₃(CO)₁₂ precursor vapor, and enable deposition of a Ru metal film on the patterned substrate 125. The substrate holder 120 is heated to a pre-determined temperature that is suitable for depositing the desired Ru metal film onto the patterned substrate 125. Additionally, a heater (not shown) coupled to a chamber temperature control system 121 can be embedded in the walls of process chamber 110 to heat the chamber walls to a pre-determined temperature. The heater can maintain the temperature of the walls of process chamber 110 from about 40° C. to about 150° C., or from about 40° C. to about 80° C. A pressure gauge (not shown) is used to measure the process chamber pressure. According to an embodiment of the invention, the process chamber pressure can be between about 1 mTorr and about 500 mTorr. Alternately, the process chamber pressure can be between about 10 mTorr and about 100 mTorr.

Also shown in FIG. 6, a vapor distribution system 130 is coupled to the upper chamber section 111 of process chamber 110. Vapor distribution system 130 comprises a vapor distribution plate 131 configured to introduce precursor vapor from vapor distribution plenum 132 to a processing zone 133 above the patterned substrate 125 through one or more orifices 134.

Furthermore, an opening 135 is provided in the upper chamber section 111 for introducing a process gas containing Ru₃(CO)₁₂ precursor vapor and CO gas from vapor precursor delivery system 140 into vapor distribution plenum 132. Moreover, temperature control elements 136, such as concentric fluid channels configured to flow a cooled or heated fluid, are provided for controlling the temperature of the vapor distribution system 130, and thereby prevent the decomposition or condensation of the Ru₃(CO)₁₂ precursor vapor inside the vapor distribution system 130. For instance, a fluid, such as water, can be supplied to the fluid channels from a vapor distribution temperature control system 138. The vapor distribution temperature control system 138 can include a fluid source, a heat exchanger, one or more temperature sensors for measuring the fluid temperature or vapor distribution plate temperature or both, and a controller configured to control the temperature of the vapor distribution plate 131 from about 20° C. to about 150° C. For a Ru₃(CO)₁₂ precursor, the temperature of the vapor distribution plate 131 can be maintained at or above a temperature of about 65° C. to avoid precursor condensation on the vapor distribution plate 131.

As illustrated in FIG. 6, a metal precursor vaporization system 150 is configured to hold a Ru₃(CO)₁₂ precursor 152 and to evaporate (or sublime) the Ru₃(CO)₁₂ precursor 152 by elevating the temperature of the Ru₃(CO)₁₂ precursor. The terms “vaporization,” “sublimation” and “evaporation” are used interchangeably herein to refer to the general formation of a vapor (gas) from a solid or liquid precursor, regardless of whether the transformation is, for example, from solid to liquid to gas, solid to gas, or liquid to gas. A precursor heater 154 is provided for heating the Ru₃(CO)₁₂ precursor 152 to maintain the Ru₃(CO)₁₂ precursor 152 at a temperature that produces a desired vapor pressure of Ru₃(CO)₁₂ precursor 152. The precursor heater 154 is coupled to a vaporization temperature control system 156 configured to control the temperature of the Ru₃(CO)₁₂ precursor 152. For example, the precursor heater 154 can be configured to adjust the temperature of the Ru₃(CO)₁₂ precursor 152 from about 40° C. to about 150° C., or from about 60° C. to about 90° C.

As the Ru₃(CO)₁₂ precursor 152 is heated to cause evaporation (or sublimation), a CO-containing gas can be passed over or through the Ru₃(CO)₁₂ precursor 152 to capture the Ru₃(CO)₁₂ precursor vapor as the Ru₃(CO)₁₂ precursor vapor is being formed. The CO-containing gas contains CO and optionally an inert carrier gas, such as N₂, or a noble gas (i.e., He, Ne, Ar, Kr, Xe). For example, a gas supply system 160 is coupled to the metal precursor vaporization system 150, and is configured to, for instance, flow the CO gas over or through the Ru₃(CO)₁₂ precursor 152. Although not shown in FIG. 6, gas supply system 160 can also be coupled to the vapor precursor delivery system 140 to supply the CO gas to the vapor of the Ru₃(CO)₁₂ precursor 152 as or after the vapor of the Ru₃(CO)₁₂ precursor 152 enters the vapor precursor delivery system 140, for example, to pre-treat the patterned substrate 125 with a pre-treatment gas containing CO gas to saturate the exposed surfaces of the patterned substrate 125 with adsorbed CO prior to exposing the patterned substrate 125 to a process gas containing Ru₃(CO)₁₂ precursor vapor and CO gas.

The gas supply system 160 can comprise a gas source 161 containing an inert carrier gas, a CO gas, or a mixture thereof, one or more control valves 162, one or more filters 164, and a mass flow controller 165. For instance, the mass flow rate of the CO-containing gas can range from approximately 0.1 sccm to approximately 1000 sccm.

Additionally, a sensor 166 is provided for measuring the total gas flow from the metal precursor vaporization system 150. The sensor 166 can, for example, comprise a mass flow controller, and the amount of Ru₃(CO)₁₂ precursor vapor delivered to the process chamber 110 can be determined using sensor 166 and mass flow controller 165. Alternately, the sensor 166 can comprise a light absorption sensor to measure the concentration of the Ru₃(CO)₁₂ precursor in the gas flow to the process chamber 110.

A bypass line 167 can be located downstream from sensor 166, and the bypass line 167 can connect the vapor precursor delivery system 140 to an exhaust line 116. Bypass line 167 is provided for evacuating the vapor precursor delivery system 140, and for stabilizing the supply of the Ru₃(CO)₁₂ precursor vapor and CO gas to the process chamber 110. In addition, a bypass valve 168, located downstream from the branching of the vapor precursor delivery system 140, is provided on bypass line 167.

Referring still to FIG. 6, the vapor precursor delivery system 140 comprises a high conductance vapor line having first and second valves 141 and 142, respectively. Additionally, the vapor precursor delivery system 140 can further comprise a vapor line temperature control system 143 configured to heat the vapor precursor delivery system 140 via heaters (not shown). The temperatures of the vapor lines can be controlled to avoid condensation of the Ru₃(CO)₁₂ precursor vapor in the vapor line. The temperature of the vapor lines can be controlled from about 20° C. to about 100° C., or from about 40° C. to about 90° C.

Moreover, a CO gas can be supplied from a gas supply system 190. For example, the gas supply system 190 is coupled to the vapor precursor delivery system 140, and it is configured to, for instance, pre-treat the patterned substrate 125 with a pre-treatment gas containing a CO gas or mix additional CO gas with the Ru₃(CO)₁₂ precursor vapor in the vapor precursor delivery system 140, for example, downstream of valve 141. The gas supply system 190 can comprise a CO gas source 191, one or more control valves 192, one or more filters 194, and a mass flow controller 195. For instance, the mass flow rate of CO gas can range from approximately 0.1 sccm to approximately 1000 sccm.

Mass flow controllers 165 and 195, and valves 162, 192, 168, 141, and 142 are controlled by controller 196, which controls the supply, shutoff, and the flow of the inert carrier gas, the CO gas, and the Ru₃(CO)₁₂ precursor vapor. Sensor 166 is also connected to controller 196 and, based on output of the sensor 166, controller 196 can control the carrier gas flow through mass flow controller 165 to obtain the desired Ru₃(CO)₁₂ precursor flow to the process chamber 110.

As illustrated in FIG. 6, the exhaust line 116 connects exhaust chamber 113 to vacuum pumping system 118. A vacuum pump 119 is used to evacuate process chamber 110 to the desired degree of vacuum, and to remove gaseous species from the process chamber 110 during processing. An automatic pressure controller (APC) 115 and a trap 117 can be used in series with the vacuum pump 119. The vacuum pump 119 can include a turbo-molecular pump (TMP) capable of a pumping speed up to 500 liters per second (and greater). Alternately, the vacuum pump 119 can include a dry roughing pump. During processing, the process gas can be introduced into the process chamber 110, and the chamber pressure can be adjusted by the APC 115. The APC 115 can comprise a butterfly-type valve or a gate valve. The trap 117 can collect unreacted Ru₃(CO)₁₂ precursor material and by-products from the process chamber 110.

Referring back to the substrate holder 120 in the process chamber 110, as shown in FIG. 6, three substrate lift pins 127 (only two are shown) are provided for holding, raising, and lowering the patterned substrate 125. The substrate lift pins 127 are coupled to plate 123, and can be lowered to below the upper surface of substrate holder 120. A drive mechanism 129 utilizing, for example, an air cylinder provides means for raising and lowering the plate 123. The patterned substrate 125 can be transferred into and out of process chamber 110 through gate valve 200 and chamber feed-through passage 202 via a robotic transfer system (not shown), and received by the substrate lift pins 127. Once the patterned substrate 125 is received from the transfer system, the patterned substrate 125 can be lowered to the upper surface of the substrate holder 120 by lowering the substrate lift pins 127.

Still referring to FIG. 6, a deposition system controller 180 includes a microprocessor, a memory, and a digital I/O port capable of generating control voltages sufficient to communicate and activate inputs of the deposition system 100 as well as monitor outputs from the deposition system 100. Moreover, the controller 180 is coupled to and exchanges information with process chamber 110; precursor delivery system 105, which includes controller 196, vapor line temperature control system 143, and vaporization temperature control system 156; vapor distribution temperature control system 138; vacuum pumping system 118; and substrate holder temperature control system 128. In the vacuum pumping system 118, the controller 180 is coupled to and exchanges information with the APC 115 for controlling the pressure in the process chamber 110. A program stored in the memory is utilized to control the aforementioned components of the deposition system 100 according to a stored process recipe.

The controller 180 may be implemented as a general purpose computer system that performs a portion or all of the microprocessor-based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 180 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the controller 180, for driving a device or devices for implementing the invention, and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 180 for execution. A computer readable medium may take many forms, including but not limited to, non-volatile media, volatile media, and transmission media. Non-volatile media includes, for example, optical disks, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to the processor of the controller for execution. For example, the instructions may initially be carried on a magnetic disk of a remote computer. The remote computer can load the instructions for implementing all or a portion of the present invention remotely into a dynamic memory and send the instructions over a network to the controller 180.

The controller 180 may be locally located relative to the deposition system 100, or the controller 180 may be remotely located relative to the deposition system 100. For example, the controller 180 may exchange data with the deposition system 100 using at least one of a direct connection, an intranet, the Internet or a wireless connection. The controller 180 may be coupled to an intranet at, for example, a customer site (i.e., a device maker, etc.), or it may be coupled to an intranet at, for example, a vendor site (i.e., an equipment manufacturer). Additionally, for example, the controller 180 may be coupled to the Internet. Furthermore, another computer (i.e., controller, server, etc.) may access, for example, the controller 180 to exchange data via at least one of a direct connection, an intranet, and the Internet. As also would be appreciated by those skilled in the art, the controller 180 may exchange data with the deposition system 100 via a wireless connection.

A plurality of embodiments for integrating selective Ru deposition into manufacturing of semiconductor devices to improve EM and SM in Cu metallization has been disclosed in various embodiments. The foregoing description of the embodiments of the invention has been presented for the purposes of illustration and description and is not intended to be exhaustive or to limit the invention to the precise forms disclosed. This description and the claims following include terms that are used for descriptive purposes only and are not to be construed as limiting. For example, the term “on” as used herein (including in the claims) does not require that a film “on” a patterned substrate is directly on and in immediate contact with the substrate; there may be a second film or other structure between the film and the substrate.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of forming a semiconductor device, comprising:
providing a patterned substrate on a substrate holder in a plasma processing chamber, the patterned substrate containing a recessed feature formed in a low-k dielectric material and a first metallization layer at the bottom on the recessed feature;
treating the patterned substrate with NHₓ (x≦3) radicals and H radicals formed in the plasma processing chamber from a first process gas comprising NH₃;
forming a first ruthenium (Ru) metal cap layer on the first metallization layer;
depositing a barrier layer in the recessed feature, including on the low-k dielectric material and on the first Ru metal cap layer; and
filling the recessed feature with copper (Cu) metal.

2. The method of claim 1, wherein treating the patterned substrate further comprises a gas pressure greater than 1 Torr for the first process gas in the plasma processing chamber.

3. The method of claim 1, wherein treating the patterned substrate further comprises generating a plasma from the first process gas by applying RF power of less than 100 W to the substrate holder.

4. The method of claim 1, wherein treating the patterned substrate suppresses exposure of the patterned substrate to ions.

5. The method of claim 1, wherein the forming comprises selectively forming a first Ru metal cap layer on the first metallization layer relative to on the low-k dielectric material.

6. The method of claim 1, wherein the first process gas consists of NH₃.

7. The method of claim 1, wherein the low-k dielectric material comprises a SiCOH material.

8. The method of claim 1, wherein forming the first Ru metal cap layer comprises exposing the patterned substrate to a deposition gas containing Ru₃(CO)₁₂ precursor vapor and a CO gas in a thermal chemical vapor deposition process.

9. The method of claim 1, further comprising:
following the filling, forming a substantially planar surface with Cu paths and low-k dielectric regions;
treating the Cu paths and the low-k dielectric regions with NHₓ (x≦3) radicals and H radicals formed in the plasma processing chamber from a second process gas comprising NH₃; and
forming a second Ru metal cap layer on the treated Cu paths.

10. The method of claim 9, wherein treating the Cu paths and the low-k dielectric regions further comprises a gas pressure greater than 1 Torr for the second process gas in the plasma processing chamber.

11. The method of claim 9, wherein treating the Cu paths and the low-k dielectric regions further comprises generating a plasma from the second process gas by applying RF power of less than 100 W to the substrate holder.

12. The method of claim 9, wherein treating the Cu paths and the low-k dielectric regions suppresses exposure of the Cu paths and the low-k dielectric regions to ions.

13. A method of forming a semiconductor device, comprising:
providing a patterned substrate on a substrate holder in a plasma processing chamber, the patterned substrate having a substantially planar surface with copper (Cu) paths and low-k dielectric regions;
treating the Cu paths and the low-k dielectric regions with NHₓ (x≦3) radicals and H radicals formed in the plasma processing chamber from a process gas comprising NH₃; and
forming a ruthenium (Ru) metal cap layer on the treated Cu paths.

14. The method of claim 13, wherein treating the Cu paths and the low-k dielectric regions further comprises a gas pressure greater than 1 Torr for the process gas in the plasma processing chamber.

15. The method of claim 13, wherein treating the Cu paths and the low-k dielectric regions further comprises generating a plasma from the process gas by applying RF power of less than 100 W to the substrate holder.

16. The method of claim 13, wherein treating the Cu paths and the low-k dielectric regions suppresses exposure of the Cu paths and the low-k dielectric regions to ions.

17. The method of claim 13, wherein the forming comprises selectively forming a Ru metal cap layer on the Cu paths relative to on the low-k dielectric regions.

18. The method of claim 13, wherein the process gas consists of NH₃.

19. The method of claim 13, wherein the low-k dielectric material comprises a SiCOH material.

20. The method of claim 13, wherein forming the Ru metal cap layer comprises exposing the Cu paths and the low-k dielectric regions to a deposition gas containing Ru₃(CO)₁₂ precursor vapor and a CO gas in a thermal chemical vapor deposition process.
